(19) United States
(12) Patent Application Publication
(10) Pub. No.: US 2014/0124013 A1
(43) Pub. Date: May 8, 2014

(54) HIGH EFFICIENCY CONFIGURATION FOR SOLAR CELL STRING

(71) Applicant: COGENRA SOLAR, INC., Mountain View, CA (US)

(72) Inventors: Ratson MORAD, Palo Alto, CA (US); Nathan P. Beckett, Oakland, CA (US); John Anthony GANNON, Palo Alto, CA (US); Gilad ALMOGY, Palo Alto, CA (US)

(73) Assignee: COGENRA SOLAR, INC., MOUNTAIN VIEW, CA (US)

(21) Appl. No.: 13/672,386

(22) Filed: Nov. 8, 2012

(51) Int. Cl. H01L 31/05; H01L 31/052; H01L 31/0224

(52) U.S. Cl. CPC H01L 31/0504; H01L 31/022433; H01L 31/0522
USPC 136/246; 136/256; 136/244

(57) ABSTRACT

A high efficiency configuration for a string of solar cells comprises series-connected solar cells arranged in an overlapping shingle pattern. Mechanically compliant electrical interconnects may electrically couple two or more such strings in series, for example. Front and back surface metallization patterns may provide further increases in efficiency.

### FIELD OF THE INVENTION

The invention relates generally to solar cells.

### BACKGROUND

Alternate sources of energy are needed to satisfy ever increasing world-wide energy demands. Solar energy resources are sufficient in many geographical regions to satisfy such demands, in part, by provision of electric power generated with solar (e.g., photovoltaic) cells.

### SUMMARY

High efficiency arrangements of solar cells are disclosed herein. Solar cells and strings of solar cells as disclosed herein may be particularly valuable in concentrating photovoltaic systems, in which mirrors or lenses concentrate sunlight onto a photovoltaic cell to light intensities greater than one “sun.”

In one aspect, a solar cell comprises a silicon semiconductor diode structure having rectangular or substantially rectangular front and back surfaces that have shapes defined by first and second oppositely positioned long sides of the solar cell and two oppositely positioned short sides of the solar cell. In operation, the front surface is to be illuminated by light. The solar cell comprises an electrically conducting front surface metallization pattern disposed on the front surface. This metallization pattern includes a plurality of fingers running parallel to the short sides of the solar cell for substantially the length of the short sides. An electrically conducting back surface metallization pattern is disposed on the back surface.

In some variations, the front surface metallization pattern does not include any bus bar interconnecting the fingers to collect current from the front surface of the solar cell. In such variations, the back surface metallization pattern may lack any contact pad conventionally prepared for solder connections to the solar cell. Alternatively, the back surface metallization pattern may include, for example, a contact pad positioned adjacent to and running parallel to a long side of the solar cell for substantially the length of the long side, or two or more discrete contact pads positioned adjacent to and arranged parallel to the long side.

In some variations, the front surface metallization pattern comprises only a single bus bar, which is positioned adjacent to and runs parallel to the first long side for substantially the length of the first long side. The fingers of the front metallization pattern are attached to and interconnected by the bus bar. In such variations, the back surface metallization pattern may lack any contact pad. Alternatively, the back surface metallization pattern may include, for example, a contact pad positioned adjacent to and running parallel to the second long side for substantially the length of the second long side, or two or more discrete contact pads positioned adjacent to and arranged parallel to the second long side. These contact pads may have widths measured perpendicular to the long sides that approximately match the width of the bus bar, for example. In any of these variations the front surface metallization pattern may include a bypass conductor that has a width perpendicular to its long axis narrower than the width of the bus bar and that interconnects two or more fingers to provide multiple current paths from each of the two or more interconnected fingers to the bus bar. The bypass conductor may be positioned adjacent to and run parallel to the bus bar, for example.

In some variations, the front surface metallization pattern comprises two or more discrete contact pads positioned adjacent to the first long side. Each of the fingers of the front metallization pattern is attached and electrically connected to at least one of the contact pads. In such variations, the back surface metallization pattern may lack any contact pad. Alternatively, the back surface metallization pattern may include, for example, a contact pad positioned adjacent to and running parallel to the second long side for substantially the length of the second long side, or two or more discrete contact pads positioned adjacent to and arranged parallel to the second long side. These contact pads may have widths measured perpendicular to the long sides that approximately match the width of the contact pads in the front surface metallization pattern, for example. In any of these variations the front surface metallization pattern may include a bypass conductor that has a width perpendicular to its long axis narrower than the widths of the front surface metallization contact pads and that interconnects two or more fingers to provide multiple current paths from each of the two or more interconnected fingers to one or more of the contact pads.

In any of the above variations, the ratio of the length of a long side of the solar cell to the length of a short side of the solar cell may be greater than or equal to three, for example.

A concentrating solar energy collector may comprise the solar cell of any of the above variations and optical elements arranged to concentrate solar radiation onto the solar cell.

In another aspect, a string of solar cells comprises at least a first silicon solar cell and a second silicon solar cell. The first silicon solar cell comprises a front surface to be illuminated by light, a back surface, and an electrically conducting front surface metallization pattern disposed on the front surface. The second silicon solar cell comprises a front surface to be illuminated by light, a back surface, and an electrically conductive back surface metallization pattern disposed on the back surface. The first and second silicon solar cells are positioned with an the edge of the back surface of the second silicon solar cell overlapping an edge of the front surface of the first silicon solar cell. A portion of the front surface metallization pattern of the first silicon solar cell is hidden by the second silicon solar cell and bonded to a portion of the back surface metallization pattern of the second silicon solar cell with an electrically conductive bonding material to electrically connect the first and second silicon solar cells in series.

Either or both of the first and second silicon solar cells may be, for example, any of the variations of the silicon solar cell summarized in the first aspect above. In such variations, the overlapping edges of the silicon solar cells may be defined by long sides of the solar cells, for example, and the edges may be arranged parallel to each other. If the front surface metallization pattern of the first silicon solar cell includes a bypass conductor, the bypass conductor may either be hidden, or not hidden, by the second silicon solar cell.

The first and second silicon solar cells may be bonded to each other at the overlapping portions of the solar cells with an electrically conductive solder. As an alternative to solder, the solar cells may instead be bonded to each other with, for example, an electrically conductive film, an electrically conductive paste, an electrically conductive tape, or another suitable electrically conductive adhesive. These alternatives to solder may be selected, for example, to provide more mechanical compliance than would be provided by an electrically conductive solder bond. The electrically conductive bonding material bonding the solar cells to each other may also interconnect fingers of the front surface metallization pattern to perform the current collecting function of a bus bar. The front surface metallization pattern on the first solar cell may thus lack any such bus bar.

A concentrating solar energy collector may comprise the string of solar cells of any of the above variations and optical elements arranged to concentrate solar radiation onto the string.

In another aspect, a solar energy receiver comprises a metal substrate and a series-connected string of two or more solar cells disposed on the metal substrate with ends of adjacent solar cells overlapping in a shingle pattern. Adjacent overlapping pairs of solar cells may be electrically connected in a region where they overlap by an electrically conducting bond between a metallization pattern on a front surface of one of the solar cells and a metallization pattern on a back surface of the other solar cell. The solar cells may be silicon solar cells, for example, including any of the variations of the silicon solar cell summarized in the first aspect above. The electrically conducting bond between the solar cells may be formed, for example, by any of the methods summarized in the second aspect above. The solar cells may be disposed in a lamination stack that adheres to the metal substrate, for example.

In some variations, the metal substrate is linearly elongated, each of the solar cells is linearly elongated, and the string of solar cells is arranged in a row along a long axis of the metal substrate with long axes of the solar cells oriented perpendicular to the long axis of the metal substrate. This row of solar cells may be the only row of solar cells on the substrate.

In some variations, the series-connected string of solar cells is a first string of solar cells, and the solar energy receiver comprises a second series-connected string of two or more solar cells arranged with ends of adjacent solar cells overlapping in a shingle pattern. The second string of solar cells is also disposed on the metal substrate. A mechanically compliant electrical interconnect may electrically couple a back surface metallization pattern on a solar cell at an end of the first string of solar cells to a front surface metallization pattern on a solar cell at an end of the second string of solar cells. In such variations, the metal substrate may be linearly elongated, each of the solar cells may be linearly elongated, and the first and second strings of solar cells may be arranged in line in a row along a long axis of the metal substrate with long axes of the solar cells oriented perpendicularly to the long axis of the metal substrate.

A concentrating solar energy collector may comprising the solar energy receiver of any of the above variations and optical elements arranged to concentrate solar radiation onto the receiver.

In another aspect, a string of solar cells comprises a first group of solar cells arranged with ends of adjacent solar cells overlapping in a shingle pattern and connected in series by electrical connections between solar cells made in the overlapping regions of adjacent solar cells, a second group of solar cells arranged with ends of adjacent solar cells overlapping in a shingle pattern and connected in series by electrical connections between solar cells made in the overlapping regions of adjacent solar cells, and a mechanically compliant electrical interconnect electrically coupling the first group of solar cells to the second group of solar cells in series. The mechanically compliant electrical interconnect may electrically couple a back surface metallization pattern on a solar cell at an end of the first group of solar cells to a front surface metallization pattern on a solar cell at an end of the second group of solar cells, for example.

The solar cells may be silicon solar cells, for example, including any of the variations of the silicon solar cell summarized in the first aspect above. The electrical connections between overlapping solar cells may be made, for example, using any of the methods summarized in the second aspect above.

The first and second groups of solar cells may be arranged in line in a single row. In such variations, a gap between the two groups of solar cells where they are interconnected by the mechanically compliant electrical interconnect may have a width less than or equal to about five millimeters, for example. Also in such variations, the mechanically compliant electrical interconnect may comprise a metal ribbon oriented perpendicularly to a long axis of the row of solar cells and electrically coupled to a back surface metallization pattern on a solar cell at an end of the first group of solar cells and to a front surface metallization pattern on a solar cell at an end of the second group of solar cells.

The mechanically compliant electrical interconnect in any of the above variations may comprises a metal ribbon having the form of linked flattened ovals, for example.

A concentrating solar energy collector may comprise the string of solar cells of any of the above variations and optical elements arranged to concentrate solar radiation onto the string.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1A shows a schematic diagram of an example front surface metallization pattern for a solar cell.

FIG. 1B shows a schematic diagram of an example back surface metallization pattern that may be used, for example, for a solar cell having the front surface metallization pattern of FIG. 1A.

FIG. 2 shows a fragmentary view schematically illustrating one end of an example solar energy receiver that comprises a string of series-connected solar cells arranged in an overlapping manner on a linearly elongated substrate. Each solar cell has the front surface metallization pattern illustrated in FIG. 1A.

FIG. 3 shows a schematic cross-sectional diagram illustrating the overlap of adjacent solar cells in the string of solar cells shown in FIG. 2.

FIG. 4 shows a schematic diagram of a string of solar cells including a first group of overlapped solar cells electrically connected to a second group of overlapped solar cells by an electrically conductive mechanically compliant interconnect.

FIG. 5 shows a schematic diagram of the example mechanically compliant interconnect used in the string of solar cells illustrated in FIG. 4.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

As used in this specification and the appended claims, the singular forms “a,” “an,” and “the” include plural referents unless the context clearly indicates otherwise. Also, the term “parallel” is intended to mean “parallel or substantially parallel” and to encompass minor deviations from parallel geometries rather than to require that any parallel arrangements described herein be exactly parallel. The term “perpendicular” is intended to mean “perpendicular or substantially perpendicular” and to encompass minor deviations from perpendicular geometries rather than to require that any perpendicular arrangement described herein be exactly perpendicular.

This specification discloses high efficiency configurations for solar cell strings as well as solar cells (e.g., photovoltaic cells), and electrically conductive interconnects for solar cells, that may be used in such strings. As further described below, the high efficiency configuration strings may be advantageously employed in concentrating solar energy collectors in which solar radiation is concentrated onto the solar cells with reflectors, lenses, or other optical components.

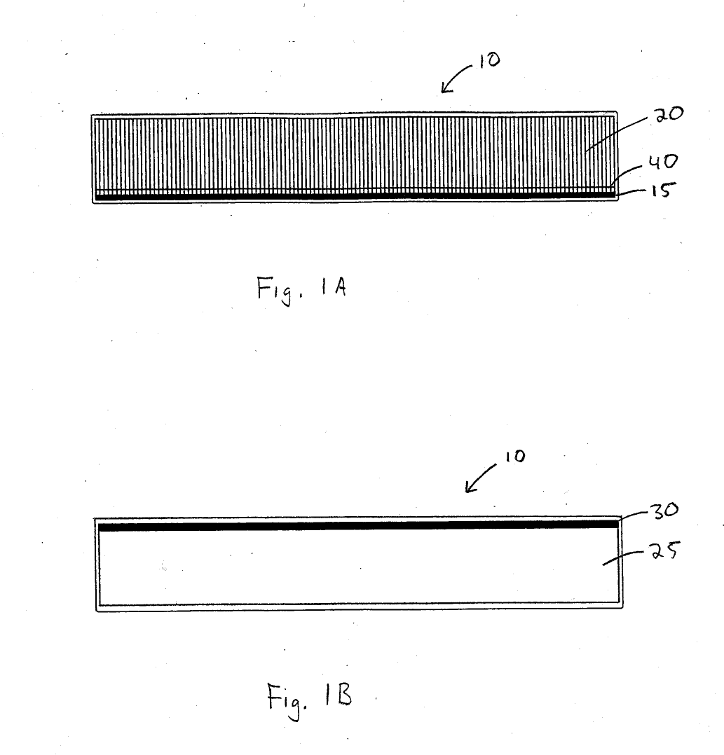

FIG. 1A shows a schematic diagram of an electrically conducting front surface metallization pattern on the front surface of an example solar cell 10. The front surface of solar cell 10 is rectangular or substantially rectangular. Other shapes may also be used, as suitable. The front surface metallization pattern includes a bus bar 15 positioned adjacent to the edge of one of the long sides of solar cell 10 and running parallel to the long sides for substantially the length of the long sides, and fingers 20 attached perpendicularly to the bus bar and running parallel to each other and to the short sides of solar cell 10 for substantially the length of the short sides.

Solar cell 10 comprises a semiconductor diode structure on which the front surface metallization pattern is disposed. A back surface metallization pattern is disposed on a back surface of solar cell 10 as shown, for example, in FIG. 1B and described further below. The semiconductor structure may be, for example, a conventional silicon diode structure comprising an n-p junction, with the top semiconductor layer on which the front surface metallization is disposed being, for example, of either n-type or p-type conductivity. Any other suitable semiconductor diode structure in any other suitable material system may also be used.

Referring now to FIG. 1B, an electrically conducting back surface metallization pattern on the back surface of solar cell 10 comprises back contact 25, and back contact pad 30 positioned adjacent to the edge of one of the long sides of solar cell 10 and running parallel to the long sides for substantially the length of the long sides. FIG. 1B shows the back side of solar cell 10 as if it were viewed through the front surface of solar cell 10. As shown by a comparison of FIG. 1A and FIG. 1B, back contact pad 30 and front surface bus bar 15 are positioned along opposite long sides of solar cell 10.

The front and rear surface metallization patterns on solar cell 10 provide electric contacts to the semiconductor diode structure by which electric current generated in solar cell 10 when it is illuminated by light may be provided to an external load. In addition, the illustrated front and back surface metallization patterns allow two such solar cells 10 to be positioned in an overlapping geometry with their long sides parallel to each other and with the back contact pad 30 of one of the solar cells overlapping and physically and electrically connected to the front surface bus bar 15 of the other solar cell. As further described below, this pattern may be continued, in a manner similar to shingling a roof, to construct a string of two or more overlapping solar cells 10 electrically connected in series. Such an arrangement is referred to below as, for example, series-connected overlapping solar cells.

In the illustrated example solar cell 10 has a length of about 156 millimeters (mm), a width of about 26 mm, and thus an aspect ratio (length of short side/length of long side) of about 1:6. Six such solar cells may be prepared on a standard 156 mm×156 mm dimension silicon wafer, then separated (diced) to provide solar cells as illustrated. In other variations, eight solar cells 10 having dimensions of about 19.5 mm×156 mm, and thus an aspect ratio of about 1:8, may be prepared from a standard silicon wafer. More generally, solar cells 10 may have aspect ratios of, for example, about 1:3 to about 1:20 and may be prepared from standard size wafers or from wafers of any other suitable dimensions. As further explained below, solar cells having long and narrow aspect ratios, as illustrated, may be advantageously employed in concentrating photovoltaic solar energy collectors in which solar radiation is concentrated onto the solar cells.

Referring again to FIG. 1A, in the illustrated example the front surface metallization pattern on solar cell 10 also comprises an optional bypass conductor 40 running parallel to and spaced apart from bus bar 15. Bypass conductor 40 interconnects fingers 20 to electrically bypass cracks that may form between bus bar 15 and bypass conductor 40. Such cracks, which may sever fingers 20 at locations near to bus bar 15, may otherwise isolate regions of solar cell 10 from bus bar 15. The bypass conductor provides an alternative electrical path between such severed fingers and the bus bar. A bypass conductor 40 may have a width, for example, of less than or equal to about 1 mm, less than or equal to about 0.5 mm, or between about 0.05 mm and about 0.5 mm. The illustrated example shows a bypass conductor 40 positioned parallel to bus bar 15, extending about the full length of the bus bar, and interconnecting every finger 20. This arrangement may be preferred but is not required. If present, the bypass conductor need not run parallel to the bus bar and need not extend the full length of the bus bar. Further, a bypass conductor interconnects at least two fingers, but need not interconnect all fingers. Two or more short bypass conductors may be used in place of a longer bypass conductor, for example. Any suitable arrangement of bypass conductors may be used. The use of such bypass conductors is described in greater detail in U.S. patent application Ser. No. 13/371,790, titled “Solar Cell With Metallization Compensating For Or Preventing Cracking,” and filed Feb. 13, 2012, which is incorporated herein by reference in its entirety.

Bus bar 15, fingers 20, and bypass conductor 40 (if present) of the front surface metallization pattern may be formed, for example, from silver paste conventionally used for such purposes and deposited, for example, by conventional screen printing methods. Alternatively, these features may be formed from electroplated copper. Any other suitable materials and processes may be also used. Bus bar 15 may have a width perpendicular to its long axis of, for example, less than or equal to about 3 mm, and in the illustrated example has a width of about 1.5 mm. Fingers 20 may have widths, for example, of about 10 microns to about 100 microns. In the illustrated example, the front surface metallization pattern includes about 125 fingers spaced evenly along the ˜154 mm length of bus bar 15. Other variations may employ, for example, less than about 125, about 150, about 175, about 200, about 225, about 125 to about 225, or more than about 225 fingers spaced evenly along a bus bar 15 of about the same (˜154 mm) length. Generally, the width of the bus bar and the width, number, and spacing of the fingers may be varied depending on the intensity of solar radiation to be concentrated on the solar cell. Typically, higher concentrations of solar radiation on the solar cell require more and/or wider fingers to accommodate the resulting higher current generated in the solar cell. In some variations, the fingers may have widths that are greater near the bus bar than they are away from the bus bar.

Referring again to the example back surface metallization pattern shown in FIG. 1B, back contact 25 may be a conventionally deposited aluminum contact, for example, and may substantially cover the back surface of solar cell 10. Alternatively, back contact 25 may leave islands or other portions of the back surface of solar cell 10 unmetallized. As yet another alternative, back contact 25 may comprise fingers similar to those in the front surface metallization pattern, running parallel to each other and to the short sides of solar cell 10 for substantially the length of the short sides. Any other suitable configuration for back contact 25 may also be used. Back contact pad 30 may be formed, for example, from silver paste conventionally used for such purposes and deposited, for example, by conventional screen printing methods. Alternatively, contact 25 and/or back contact pad 30 may be formed from electroplated copper. Any other suitable materials and processes may also be used to form back contact 25 and back contact pad 30. Back contact pad 30 may have a width perpendicular to its long axis of, for example, less than or equal to about 3 mm, and in the illustrated example has a width of about 2 mm. Back contact pad 30 may have a width, for example, matching or approximately matching the width of front bus bar 15. In such instances back contact pad 30 may have a width, for example, of about 1 to about 3 times the width of bus bar 15.

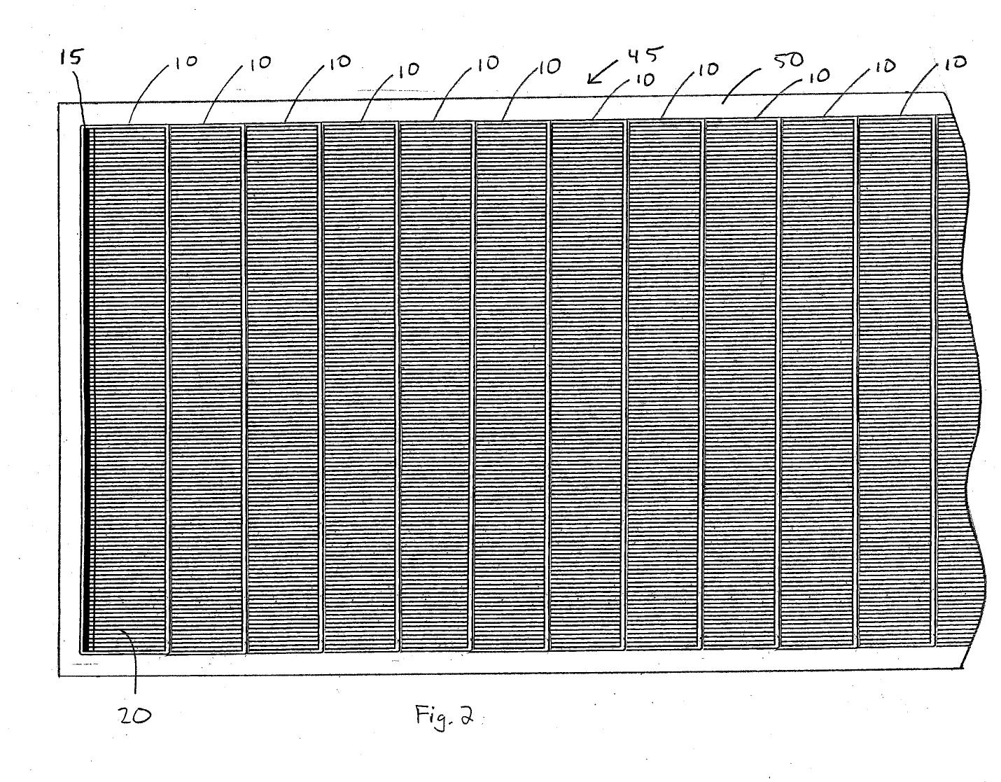

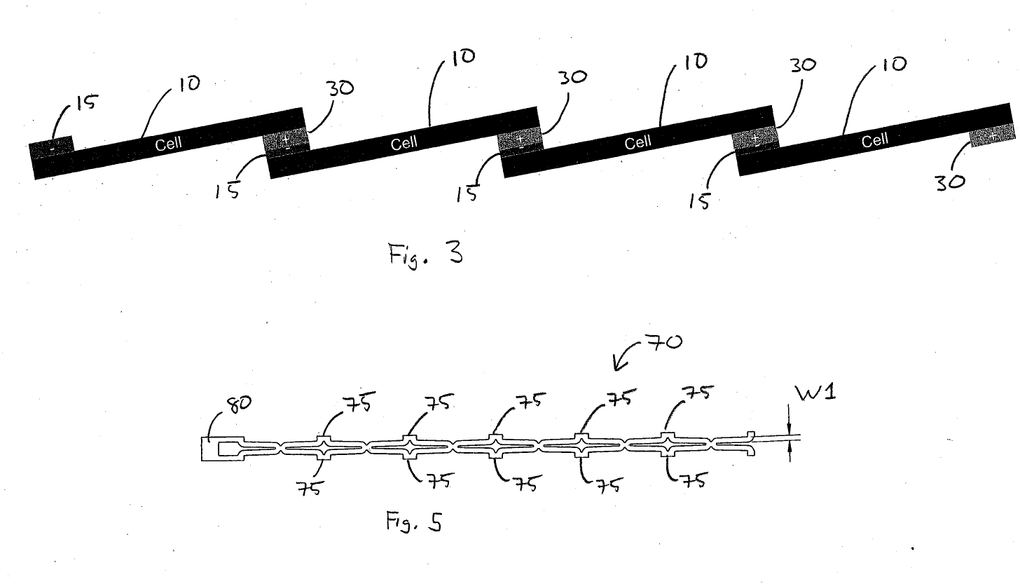

Referring now to FIG. 2, an example solar energy receiver 45 comprises a string of series-connected solar cells 10 arranged in an overlapping manner on a linearly elongated substrate 50. Each solar cell 10 in solar energy receiver 45 has the front and back surface metallization patterns illustrated in FIGS. 1A and 1B, respectively. FIG. 3 shows a cross-sectional view illustrating the overlap of adjacent solar cells in solar energy receiver 45. As shown in FIG. 3, for each pair of overlapping solar cells the bottom contact pad 30 of one solar cell overlaps the front surface bus bar 15 of the other solar cell. Exposed front surface bus bar 15 at one end of the string and exposed bottom contact pad 30 at the other end of the string may be used to electrically connect the string to other electrical components as desired. In the example illustrated in FIG. 2, bypass conductors 40 are hidden by overlapping portions of adjacent cells. Alternatively, solar cells comprising bypass conductors 40 may be overlapped similarly to as shown in FIG. 2 and FIG. 3 without covering the bypass conductors.

Front surface bus bar 15 and bottom contact pad 30 of an overlapping pair of solar cells 10 may be bonded to each other using any suitable electrically conductive bonding material. Suitable conductive bonding materials may include, for example, conventional electrically conductive reflowed solder, and electrically conductive adhesives. Suitable electrically conductive adhesives may include, for example, interconnect pastes, conductive films, and anisotropic conductive films available from Hitachi Chemical and other suppliers, as well as electrically conductive tapes available from Adhesives Research Inc., of Glen Rock Pa., and other suppliers.

The illustration of FIG. 3 labels front bus bars 15 with a minus sign (−), and bottom contact pads 30 with a plus sign (+), to indicate electrical contact to n-type and p-type conductivity layers in the solar cell, respectively. This labeling is not intended to be limiting. As noted above, solar cells 10 may have any suitable diode structure.

Referring again to FIG. 2, substrate 50 of solar energy receiver 45 may be, for example, an aluminum or other metal substrate, a glass substrate, or a substrate formed from any other suitable material. Solar cells 10 may be attached to substrate 50 in any suitable manner. For example, solar cells 10 may be laminated to an aluminum or other metal substrate 50 with intervening adhesive, encapsulant, and/or electrically insulating layers disposed between solar cells 10 and the surface of the metal substrate. Substrate 50 may optionally comprise channels through which a liquid may be flowed to extract heat from solar energy receiver 45 and thereby cool solar cells 10, in which case substrate 50 may be an extruded metal substrate. Solar energy receiver 45 may employ, for example, lamination structures, substrate configurations, and other receiver components or features as disclosed in U.S. patent application Ser. No. 12/622,416, titled “Receiver for Concentrating Solar Photovoltaic-Thermal System”, and filed Nov. 19, 2009, which is incorporated herein by reference in its entirety. Although in the illustrated example substrate 50 is linearly elongated, any other suitable shape for substrate 50 may also be used.

Receiver 45 may include only a single row of solar cells running along its length, as shown in FIG. 2. Alternatively, receiver 45 may include two or more parallel rows of solar cells running along its length.

Strings of overlapping series-connected solar cells as disclosed herein, and linearly elongated receivers including such strings, may be used, for example, in solar energy collectors that concentrate solar radiation to a linear focus along the length of the receiver, parallel to the string of solar cells. Concentrating solar energy collectors that may advantageously employ strings of series-connected overlapping solar cells as disclosed herein may include, for example, the solar energy collectors disclosed in U.S. patent application Ser. No. 12/781,706, titled “Concentrating Solar Energy Collector”, and filed May 17, 2010, which is incorporated herein by reference in its entirety. Such concentrating solar energy collectors may, for example, employ long narrow flat mirrors arranged to approximate a parabolic trough that concentrates solar radiation to a linear focus on the receiver.

Referring again to FIGS. 1A and 1B, although the illustrated examples show front bus bar 15 and back contact pad 30 each extending substantially the length of the long sides of solar cell 10 with uniform widths, this may be advantageous but is not required. For example, front bus bar 15 may be replaced by two or more discrete contact pads which may be arranged, for example, in line with each other along a side of solar cell 10. Such discrete contact pads may optionally be interconnected by thinner conductors running between them. There may be a separate (e.g., small) contact pad for each finger in the front surface metallization pattern, or each contact pad may be connected to two or more fingers. Back contact pad 30 may similarly be replaced by two or more discrete contact pads. Front bus bar 15 may be continuous as shown in FIG. 1A, and back contact pad 30 formed from discrete contact pads as just described. Alternatively, front bus bar 15 may be formed from discrete contact pads, and back contact pad 30 formed as shown in FIG. 1B. As yet another alternative, both of front bus bar 15 and back contact pad 30 may be replaced by two or more discrete contact pads. In these variations, the current-collecting functions that would otherwise be performed by front bus bar 15, back contact pad 30, or by front bus bar 15 and back contact pad 30 may instead be performed, or partially performed, by the conductive material used to bond two solar cells 10 to each other in the overlapping configuration described above.

Further, solar cell 10 may lack front bus bar 15 and include only fingers 20 in the front surface metallization pattern, or lack back contact pad 30 and include only contact 25 in the back surface metallization pattern, or lack front bus bar 15 and lack back contact pad 30. In these variations as well, the current-collecting functions that would otherwise be performed by front bus bar 15, back contact pad 30, or front bus bar 15 and back contact pad 30 may instead be performed by the conductive material used to bond two solar cells 10 to each other in the overlapping configuration described above.

Solar cells lacking bus bar 15, or having bus bar 15 replaced by discrete contact pads, may either include bypass conductor 40, or not include bypass conductor 40. If bus bar 15 is absent, bypass conductor 40 may be arranged to bypasses cracks that form between the bypass conductor and the portion of the front surface metallization pattern that is conductively bonded to the overlapping solar cell.

The strings of overlapping series-connected solar cells disclosed herein, and linearly elongated receivers including such strings, may operate with higher efficiency than conventional arrangements, particularly under concentrated illumination. In some variations, the strings of overlapping solar cells disclosed herein may provide, for example, ≧15% more output power than analogous conventionally tabbed strings of solar cells.

Dicing a wafer to provide solar cells having smaller areas reduces the current “I” generated in the solar cells and can thereby reduce “I²R” power losses that result from resistance “R” internal to the solar cells and resistance in connections between the solar cells in a string. However, conventional strings of series-connected solar cells require gaps between adjacent solar cells. For a string of a given physical length, the number of such gaps increases as the solar cells are made shorter. Each gap reduces the power generated by the string, thereby at least partially defeating the advantage that might otherwise result from using solar cells of smaller areas. Further, the power loss resulting from the gaps increases when such a conventional string is employed in a concentrating solar energy collector.

In contrast to conventional strings of solar cells, the strings of series-connected overlapping solar cells disclosed herein do not have gaps between solar cells. The solar cells in such strings may therefore be diced into smaller areas to reduce I²R losses without accumulating power losses due to gaps. For example, it may be advantageous to use solar cells having a longest side that has a length that spans a standard wafer, as in solar cells 10 depicted in the various figures herein, because such solar cells may be oriented with their longest sides perpendicular to the long axis of the string to provide a wider focal region in a linear focus concentrating solar energy collector. (Making the focal region wider relaxes tolerances on optical elements in the concentrating solar energy collector, and may facilitate advantageous use of flat mirrors). For conventional strings of solar cells, the optimal length of the short side of the solar cells would then be determined in part by a trade-off between I²R power losses and losses due to gaps between cells. For the strings of overlapping solar cells disclosed herein, the length of the short sides of the solar cells (and thus the areas of the solar cells) may be selected to reduce I²R losses to a desired level without concern for losses due to gaps.

Conventional solar cells typically employ two or more parallel front surface bus bars which shade the underlying portions of the solar cells and thus reduce the power generated by each solar cell. This problem is exacerbated by the copper ribbons, typically wider than the bus bars, which are used in conventional strings to electrically connect the front surface bus bars of a solar cell to the back surface contact of an adjacent solar cell in the string. The copper ribbons in such conventional strings typically run across the front surface of the solar cells, parallel to the string and overlying the bus bars. The power losses that result from shading by the bus bars and by the copper ribbons increase when such conventional solar cells are employed in a concentrating solar energy collector. In contrast, the solar cells disclosed herein may employ only a single bus bar on their front surfaces, as illustrated, or no bus bar, and do not require copper ribbons running across the front surface of the solar cells. Further, in strings of overlapping solar cells as disclosed herein, the front surface bus bar on each solar cell, if present, may be hidden by active surface area of an overlapping solar cell, except at one end of the string. The solar cells and strings of solar cells disclosed herein may thus significantly reduce losses due to shading of underlying portions of the solar cells by the front surface metallization, compared to conventional configurations.

One component of I²R power losses is due to the current paths through the fingers in the front surface metallization. In conventionally arranged strings of solar cells, the bus bars on the front surfaces of solar cells are oriented parallel to the length of the string, and the fingers are oriented perpendicularly to the length of the string. Current within a solar cell flows primarily perpendicularly to the length of the string along the fingers to reach the bus bars. The finger lengths required in such geometries may be sufficiently long to result in significant I²R power losses in the fingers. In contrast, the fingers in the front surface metallization of solar cells disclosed herein are oriented parallel to the short sides of the solar cells and parallel to the length of the string, and current in a solar cell flows primarily parallel to the length of the string along the fingers. The finger lengths required in this arrangement may be shorter than required for conventional cells, thus reducing power losses.

The solar cell metallization patterns and overlapping cell geometries disclosed herein may be advantageously used with crystalline silicon solar cells disposed on a metal substrate, as in receiver 45 of FIG. 2, for example. One of ordinary skill in the art may find this surprising, however. If formed using conventional reflowed solder, for example, the bond between the front surface bus bar and the back surface contact pad of overlapping solar cells in a string as disclosed herein may be significantly more rigid than the electrical connections between adjacent solar cells provided by copper ribbon tabbing in conventionally tabbed strings of solar cells. Consequently, in comparison to copper ribbon tabbing, the solder connections between adjacent solar cells in such a string may provide significantly less strain relief to accommodate mismatch between the thermal expansion coefficient of the silicon solar cells and the thermal expansion coefficient of the metal substrate. One of ordinary skill in the art may therefore expect such strings of overlapping silicon solar cells disposed on a metal substrate to fail through cracking of the silicon solar cells. This expectation would be even stronger for such strings of overlapping solar cells employed in a concentrating solar energy collector in which they may reach higher temperatures, and therefore experience greater strain from thermal expansion mismatch with the substrate, than typically experienced in a non-concentrating solar energy collector.

Contrary to such expectations, however, the inventors have determined that strings of series-connected overlapping silicon solar cells may be bonded to each other with conventional reflowed solder, attached to an aluminum or other metal substrate, and reliably operated under concentrated solar radiation. Such strings may have a length, for example, of greater than or equal to about 120 mm, greater than or equal to about 200 mm, greater than or equal to about 300 mm, greater than or equal to about 400 mm, or greater than or equal to about 500 mm, or between about 120 mm and about 500 mm.

Further, the inventors have also determined that solder substitutes such as electrically conducting tapes, conductive films, and interconnect pastes such as those described above, and other similar conducting adhesives, may be used to bond solar cells to each other to form even longer strings of series-connected overlapping solar cells on a metal substrate. In such variations the conductive bonding material that bonds overlapping cells together is selected to be mechanically compliant, by which it is meant that the bonding material is easily elastically deformed—springy. (Mechanical compliance is the inverse of stiffness). In particular, the conductive bonds between solar cells in such strings are selected to be more mechanically compliant than solar cells 10, and more mechanically compliant than conventional reflowed solder connections that might otherwise be used between overlapping solar cells. Such mechanically compliant conductive bonds between overlapping solar cells deform without cracking, detaching from the adjacent solar cells, or otherwise failing under strain resulting from thermal expansion mismatch between solar cells 10 and substrate 50. The mechanically compliant bonds may therefore provide strain relief to a string of interconnected overlapping solar cells, thereby accommodating the thermal expansion mismatch between solar cells 10 and substrate 50 and preventing the string from failing. Such strings of series-connected overlapping silicon solar cells disposed on a metal substrate may have a length, for example, greater than or equal to about 1 meter, greater than or equal to about 2 meters, or greater than or equal to about 3 meters.

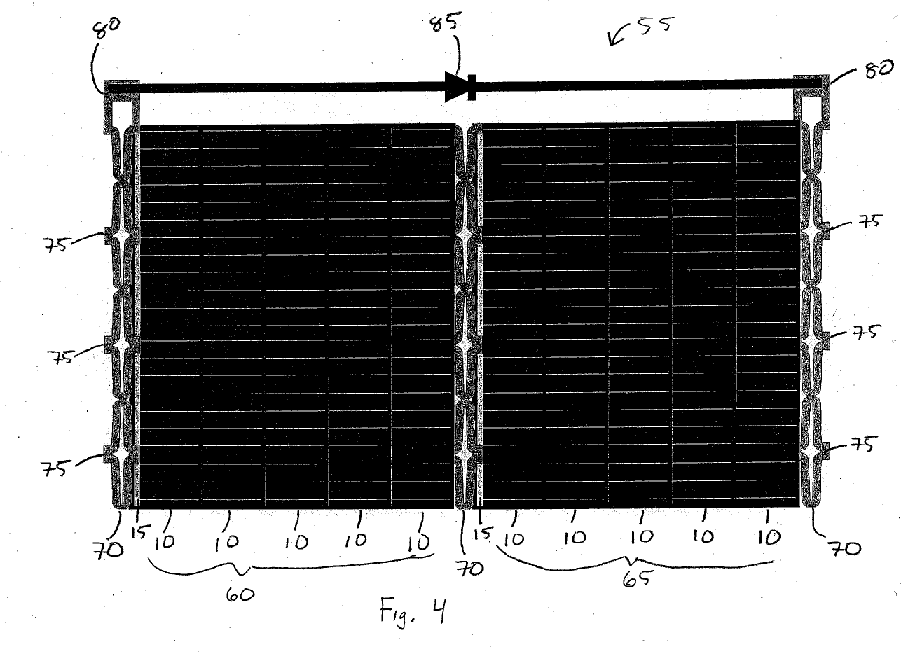

Further still, the inventors have developed mechanically compliant electrical interconnects that may be used to interconnect two or more strings of series-connected overlapping solar cells to form longer strings of series-connected solar cells. The resulting longer strings may be disposed on a metal substrate or other substrate and reliably operated under concentrated solar radiation. Referring now to FIG. 4, an example string 55 of series connected solar cells comprises a first group 60 of series-connected overlapping solar cells 10 that is electrically and physically connected to a second group 65 of series-connected overlapping solar cells 10 by a mechanically compliant electrically conductive interconnect 70. Additional such interconnects 70 are located at the ends of string 55 to allow additional groups of series-connected overlapping solar cells to be added to either end of string 55 to extend the length of the string. Alternatively, interconnects 70 located at the ends of a string may be used to connect the string to other electrical components or to an external load. Overlapping solar cells within groups 60 and 65 may be bonded to each other with electrically conductive reflowed solder or with electrically conductive adhesives, as described above, or in any other suitable manner.

The spacing between the adjacent ends of two groups of series-connected overlapping solar cells 10 interconnected with a mechanically compliant interconnect 70 may be, for example, less than or equal to about 0.2 mm, less than or equal to about 0.5 mm, less than or equal to about 1 mm, less than or equal to about 2 mm, less than or equal to about 3 mm, less than or equal to about 4 mm, or less than or equal to about 5 mm.

Referring now to FIG. 5 as well as to FIG. 4, the example mechanically compliant electrical interconnects 70 are ribbon-like and have a long and narrow aspect ratio with a length approximately equal to or greater than the length of the long sides of solar cells 10. Each interconnect 70 comprises two sets of tabs 75, with each set of tabs positioned on an opposite side of the long axis of the interconnect. As shown in FIG. 4, an interconnect 70 may be positioned between two strings of series-connected overlapping solar cells with its tabs 75 on one side making electrical contact to the exposed bus bar 15 on the front surface of an end solar cell of one string of overlapping solar cells, and with its tabs 75 on the other side making electrical contact to contact pad 30 on the back surface of an end cell of the other string of overlapping solar cells. Tabs 70 may be attached to bus bar 15 or to contact pad 30 with conventional electrically conductive solder, electrically conductive adhesives or adhesive tapes, or by any other suitable method.

In the example of FIG. 4, interconnects 70 at the end of string 55 also each include a bypass diode tap 80 at one end, in addition to tabs 75. Bypass diode taps 80 provide connection points for bypass diodes. In the illustrated example, bypass diode 85 is configured to bypass both groups of series-connected overlapping solar cells in the event that a solar cell in string 55 fails. Alternatively, interconnects 70 having bypass diode taps 80 may be used at any desired interval in a string to bypass one, two, or more groups of series-connected overlapping solar cells. The bypass diodes may be configured to bypass, for example, approximately 20 solar cells 10, which may be distributed in any desired number of series-connected groups of series-connected overlapping solar cells.

Interconnects 70 are mechanically compliant. In particular, they are more mechanically compliant than solar cells 10 and more mechanically compliant than solder connections between bus bar 15 and back contact pad 30 of overlapping solar cells 10. Interconnects 70 may also be more mechanically compliant than bonds between overlapping solar cells formed from electrically conductive adhesives as described above. Interconnects 70 deform without cracking, detaching from the adjacent solar cells, or otherwise failing under strain resulting from thermal expansion mismatch between solar cells 10 and substrate 50. Interconnects 70 may therefore provide strain relief to a string of interconnected groups of overlapping solar cells, thereby accommodating the thermal expansion mismatch between solar cells 10 and substrate 50 and preventing the string from failing.

Referring again to FIG. 5, in the illustrated example each interconnect 70 is a solder-coated metal ribbon that has been shaped to enhance its mechanical compliance. In particular, the illustrated interconnects 70 each include a central portion having the form of a series of two or more flattened ovals interlinked at their ends. Each flattened oval includes a pair of tabs 75 on opposite flattened sides of the oval, to make contact with solar cells as described above. The flattened ovals make each interconnect 70 very compliant (“springy”) in directions parallel and perpendicular to the long axis of the interconnect. In the illustrated example, the strips of metal forming the walls of the ovals have a width W1 of approximately 1.5 mm. Interconnects 70 may be formed from highly conductive materials such as copper, for example, as well as from materials such as Invar and Kovar that have a low coefficient of thermal expansion. Any other suitable materials and configurations may also be used for interconnects 70.

Although the use of interconnects 70 is described above with respect to solar cells 10 that include front surface bus bars 15 and back contact pads 30, such interconnects 70 may be used in combination with any of the variations of solar cell 10 described herein.

This disclosure is illustrative and not limiting. Further modifications will be apparent to one skilled in the art in light of this disclosure and are intended to fall within the scope of the appended claims.

What is claimed is:

1. A solar cell comprising:
a silicon semiconductor diode structure having rectangular or substantially rectangular front and back surfaces with shapes defined by first and second oppositely positioned long sides of the solar cell and two oppositely positioned short sides of the solar cell, the front surface to be illuminated by light;
an electrically conducting front surface metallization pattern disposed on the front surface and comprising a plurality of fingers running parallel to the short sides for substantially the length of the short sides; and
an electrically conducting back surface metallization pattern disposed on the back surface.

2. The solar cell of claim 1, wherein the front surface metallization pattern does not include a bus bar that interconnects the fingers.

3. The solar cell of claim 2, wherein the back surface metallization pattern comprises a contact pad positioned adjacent to and running parallel to the second long side for substantially the length of the second long side.

4. The solar cell of claim 2, wherein the back surface metallization pattern comprises two or more discrete contact pads positioned adjacent to and arranged parallel to the second long side.

5. The solar cell of claim 1, wherein the front surface metallization pattern comprises only a single bus bar, which is positioned adjacent to and runs parallel to the first long side for substantially the length of the first long side, and wherein the fingers are attached to and interconnected by the bus bar.

6. The solar cell of claim 5, comprising a bypass conductor, having a width perpendicular to its long axis narrower than the width of the bus bar, interconnecting two or more fingers to provide multiple current paths from each of the two or more interconnected fingers to the bus bar.

7. The solar cell of claim 6, wherein the bypass conductor is positioned adjacent to and runs parallel to the bus bar.

8. The solar cell of claim 5, wherein the back surface metallization pattern comprises a contact pad positioned adjacent to and running parallel to the second long side for substantially the length of the second long side.

9. The solar cell of claim 8, wherein a width of the back surface contact pad measured perpendicular to the long sides approximately matches a width of the bus bar measured perpendicular to the long sides.

10. The solar cell of claim 5, wherein the back surface metallization pattern comprises two or more discrete contact pads positioned adjacent to the second long side.

11. The solar cell of claim 1, wherein the front surface metallization pattern comprises two or more discrete contact pads positioned adjacent to the first long side, and wherein each finger is electrically connected to at least one of the contact pads.

12. The solar cell of claim 11, wherein the back surface metallization pattern comprises a contact pad positioned adjacent to and running parallel to the second long side for substantially the length of the second long side.

13. The solar cell of claim 11, wherein the back surface metallization pattern comprises two or more discrete contact pads positioned adjacent to the second long side.

14. The solar cell of claim 1, wherein the ratio of the length of a long side of the solar cell to the length of a short side of the solar cell is greater than or equal to three.

15. A concentrating solar energy collector comprising the solar cell of claim 1 and optical elements arranged to concentrate solar radiation onto the solar cell.

16. A string of solar cells comprising:
a first silicon solar cell having a front surface to be illuminated by light, a back surface, and an electrically conducting front surface metallization pattern disposed on the front surface; and
a second silicon solar cell having a front surface to be illuminated by light, a back surface, and an electrically conductive back surface metallization pattern disposed on the back surface;
wherein the first and second silicon solar cells are positioned with an the edge of the back surface of the second silicon solar cell overlapping with an edge of the front surface of the first silicon solar cell, and a portion of the front surface metallization pattern of the first silicon solar cell is hidden by the second silicon solar cell and bonded to a portion of the back surface metallization pattern of the second silicon solar cell to electrically connect the first and second silicon solar cells in series.

17. The string of solar cells of claim 16, wherein the front surface metallization pattern of the first silicon solar cell comprises a plurality of fingers oriented perpendicularly to the overlapped edge of the front surface of the first silicon solar cell.

18. The string of solar cells of claim 17, wherein the front surface metallization pattern of the first silicon solar cell comprises a bypass conductor interconnecting two or more fingers to provide multiple current paths from each of the two or more interconnected fingers to the portion of the front surface metallization pattern of the first silicon solar cell that is bonded to the second silicon solar cell.

19. The string of solar cells of claim 16, wherein:
the first and second silicon solar cells have identical or substantially identical shapes with their front and back surfaces rectangular or substantially rectangular and defined by two oppositely positioned long sides and two oppositely positioned short sides; and
the overlapping edges of the silicon solar cells are defined by long sides of the solar cells.

20. The string of solar cells of claim 19, wherein the front surface metallization pattern of the first silicon solar cell comprises a plurality of fingers oriented parallel to the short sides of the first silicon solar cell.

21. The string of solar cells of claim 16, wherein the portion of the front surface metallization pattern of the first silicon solar cell is bonded to the portion of the back surface metallization pattern of the second silicon solar cell with an electrically conductive solder.

22. The string of solar cells of claim 16, wherein the portion of the front surface metallization pattern of the first silicon solar cell is bonded to the portion of the back surface metallization pattern of the second silicon solar cell with an electrically conductive film.

23. The string of solar cells of claim 16, wherein the portion of the front surface metallization pattern of the first silicon solar cell is bonded to the portion of the back surface metallization pattern of the second silicon solar cell with an electrically conductive paste.

24. The string of solar cells of claim 16, wherein the portion of the front surface metallization pattern of the first silicon solar cell is bonded to the portion of the back surface metallization pattern of the second silicon solar cell with an electrically conductive tape.

25. The string of solar cells of claim 16, wherein the portion of the front surface metallization pattern of the first silicon solar cell is bonded to the portion of the back surface metallization pattern of the second silicon solar cell with an electrically conductive adhesive.

26. The string of solar cells of claim 16, wherein the portion of the front surface metallization pattern of the first silicon solar cell is bonded to the portion of the back surface metallization pattern of the second silicon solar cell with an electrically conductive bonding material providing more mechanical compliance than provided by an electrically conductive solder bond.

27. The string of solar cells of claim 16, wherein
the portion of the front surface metallization pattern of the first silicon solar cell is bonded to the portion of the back surface metallization pattern of the second silicon solar cell with an electrically conductive bonding material that interconnects fingers of the front surface metallization pattern to perform the current collecting function of a bus bar; and
the front surface metallization pattern of the first silicon solar cell does not include a bus bar.

28. The string of solar cells of claim 16, wherein:
the front surface metallization pattern of the first silicon solar cell includes a bus bar or a plurality of contact pads positioned adjacent to and running parallel to the overlapped edge of the front surface of the first silicon solar cell for substantially the length of that edge; and
the bus bar or plurality of contact pads on the front surface of the first silicon solar cell is hidden by the second silicon solar cell and bonded to the metallization pattern on the back surface of the second silicon solar cell to electrically connect the first and second silicon solar cells in series.

29. The string of solar cells of claim 28, wherein the front surface metallization pattern on the first silicon solar cell includes fingers attached to the bus bar or plurality of contact pads.

30. The string of solar cells of claim 28, wherein the front surface metallization pattern on the first silicon solar cell includes a bypass conductor, having a width perpendicular to its long axis narrower than the width of the bus bar or contact pads, interconnecting two or more fingers to provide multiple current paths from each of the two or more interconnected fingers to the bus bar or plurality of contact pads.

31. The string of solar cells of claim 30, wherein the bypass conductor is hidden by the second silicon solar cell.

32. The string of solar cells of claim 30, wherein the bypass conductor is not hidden by the second silicon solar cell.

33. A concentrating solar energy collector comprising the string of solar cells of claim 16 and optical elements arranged to concentrate solar radiation onto the string.

34. A solar energy receiver comprising:
a metal substrate; and
a series-connected string of two or more solar cells disposed on the metal substrate with ends of adjacent solar cells overlapping in a shingle pattern.

35. The solar energy receiver of claim 34, wherein adjacent overlapping pairs of solar cells are electrically connected in a region where they overlap by an electrically conducting bond between a metallization pattern on a front surface of one of the solar cells and a metallization pattern on a back surface of the other solar cell.

36. The solar energy receiver of claim 34, wherein the solar cells are silicon solar cells.

37. The solar energy receiver of claim 34, wherein the solar cells are disposed in a lamination stack that adheres to the metal substrate.

38. The solar energy receiver of claim 34, wherein:
the metal substrate is linearly elongated;
each of the solar cells is linearly elongated; and
the string of solar cells is arranged in a row along a long axis of the metal substrate with long axes of the solar cells oriented perpendicular to the long axis of the metal substrate.

39. The solar energy receiver of claim 38, wherein the receiver has only a single row of solar cells.

40. The solar energy receiver of claim 34, wherein the series connected string of solar cells is a first string of solar cells;
comprising a second series-connected string of two or more solar cells arranged with ends of adjacent solar cells overlapping in a shingle pattern, the second string of solar cells disposed on the metal substrate.

41. The solar energy receiver of claim 40, comprising a mechanically compliant electrical interconnect electrically coupling a back surface metallization pattern on a solar cell at an end of the first string of solar cells to a front surface metallization pattern on a solar cell at an end of the second string of solar cells.

42. The solar energy receiver of claim 41, wherein:
the metal substrate is linearly elongated;
each of the solar cells is linearly elongated; and
the first and second strings of solar cells are arranged in line in a row along a long axis of the metal substrate with long axes of the solar cells oriented perpendicular to the long axis of the metal substrate.

43. A concentrating solar energy collector comprising the solar energy receiver of claim 34 and optical elements arranged to concentrate solar radiation onto the receiver.

44. A string of solar cells comprising:
a first group of solar cells arranged with ends of adjacent solar cells overlapping in a shingle pattern and connected in series by electrical connections between solar cells made in the overlapping regions of adjacent solar cells;
a second group of solar cells arranged with ends of adjacent solar cells overlapping in a shingle pattern and connected in series by electrical connections between solar cells made in the overlapping regions of adjacent solar cells; and
a mechanically compliant electrical interconnect electrically coupling the first group of solar cells to the second group of solar cells in series.

45. The string of solar cells of claim 44, wherein the mechanically compliant electrical interconnect electrically couples a back surface metallization pattern on a solar cell at an end of the first group of solar cells to a front surface metallization pattern on a solar cell at an end of the second group of solar cells.

46. The string of solar cells of claim 44, wherein the first and second groups of solar cells are arranged in line in a single row, and a gap between the two groups of solar cells where they are interconnected by the mechanically compliant electrical interconnect has a width less than or equal to about five millimeters.

47. The string of solar cells of claim 44, wherein the mechanically compliant electrical interconnect comprises a metal ribbon having the form of linked flattened ovals.

48. The string of solar cells of claim 44, wherein:
the first and second groups of solar cells are arranged in line in a single row; and
the mechanically compliant electrical interconnect comprises a metal ribbon oriented perpendicularly to a long axis of the row of solar cells and electrically coupled to a back surface metallization pattern on a solar cell at an end of the first group of solar cells and to a front surface metallization pattern on a solar cell at an end of the second group of solar cells.

49. A concentrating solar energy collector comprising the string of solar cells of claim 44 and optical elements arranged to concentrate solar radiation onto the string.
